(19) United States
(12) Patent Application Publication
(10) Pub. No.: US 2005/0009350 A1
(43) Pub. Date: Jan. 13, 2005

(54) Carbon hard mask with bonding layer for bonding to metal

(76) Inventor: Mirko Vogt, Dresden (DE)

Correspondence Address: JENKINS & WILSON, PA, 3100 TOWER BLVD, SUITE 1400, DURHAM, NC, 27707, US

(21) Appl. No.: 10/878,458

(22) Filed: Jun. 28, 2004

(30) Foreign Application Priority Data
Jul. 8, 2003 (DE) 10330795.8

(51) Int. Cl. H01L 21/302; H01L 21/461

(52) U.S. Cl. 438/689

(57) ABSTRACT

The present invention relates to a carbon hard mask having a carbon layer and a bonding layer for bonding to metal. The present invention also relates to a process for producing this carbon hard mask, and to its use in the patterning of metallic layers, in particular in semiconductor fabrication.

The invention relates to a carbon hard mask having a carbon layer and a bonding layer for bonding to metal, to a process for producing this carbon hard mask, and to the use of the carbon hard mask according to the invention in the patterning of metallic layers.

With the ongoing miniaturization of semiconductor structures, the demands imposed on the quality and the reduction in size of metal tracks which remain after patterning of the metallic layers are also rising.

The problem in the prior art with regard to the patterning of metals, such as for example aluminum or titanium, is that the hard masks which are currently used are not optimal for the patterning of very small structures, such as those which are encountered in the 70 nm technology.

For example, if standard hard-mask materials, such as SiO or SiON, are used, defects such as Al whisker growth or Al corrosion occur. One possible cause of the occurrence of corrosion in the case of metal etching by means of a hard mask is the absence of a resist. It is assumed that the resist acts as a carbon source for passivating the metal lines using thin polymer films, thereby preventing corrosion of aluminum.

The use of carbon as a hard mask for metal etching has the drawback that, for example in the case of standard methods used for the application of carbon, such as for example PECVD (plasma enhanced chemical vapor deposition) carbon detachment is observed. The lack of bonding of the applied carbon layer occurs in particular in the region of the edge of the wafer, but constitutes a fundamental problem. The detachment at the edge of the wafer is shown by way of example in the electron microscope image, shown in FIG. 6, of the edge region of a metal-coated wafer with a carbon layer situated on the metal layer (Al). This process using a carbon hard mask first brings impurity problems and secondly defects in the pattern or topology defects.

The alternative of selecting a method in which only a resist without any hard mask is used is no longer possible with decreasing feature sizes, e.g. in the 70 nm technology, on account of the high metal layer thicknesses combined, at the same time, with small lateral dimensions of the metal. Etching with a resist alone is insufficiently precise for this. The resist budget (resist thickness) is insufficient for metal etching. The maximum resist thickness is limited by 2 factors:
1. The aspect ratio (resist height/width): if the aspect ratio is too high (approx.>3), the tracks break down.
2. The depth of focus in the photolithographic exposure process.

Therefore, it is an object of the present invention to provide a hard mask for the patterning of metal which allows the metal below to be reliably patterned or etched, even with small feature sizes, without the abovementioned problems arising.

According to the invention, this is achieved by a carbon hard mask in accordance with claim 1, which includes a carbon layer and a bonding layer for bonding to metal. The carbon hard mask according to the invention can therefore be regarded as comprising two layers, namely a carbon layer and a bonding layer arranged on the metal side, which ensures improved bonding of the carbon layer to metal.

In a particularly preferred embodiment of the present invention, the bonding layer of the carbon hard mask is a nitrogen-doped carbon layer. The problem of the poor bonding of carbon to metal can thereby be resolved. Moreover, as described further below the nitrogen-doped carbon layer can easily be integrated in the process of applying the carbon hard mask to the metal.

This nitrogen-doped carbon layer preferably has a nitrogen doping concentration of from 1 to 10% by weight, based on the total composition of the bonding layer, more preferably approximately 5% by weight. It has been established that particularly good bonding and results have been obtained in this concentration range.

There are no particular restrictions on the layer thickness of the bonding layer. For practical purposes, the thickness of the bonding layer is preferably approximately 2 to 100 nm, more preferably approximately 5 to 30 nm.

The thickness of the carbon layer is likewise not particularly restricted. Preferably, it is usually approximately 80 to 500 nm, more preferably approximately 200 to 500 nm.

In one alternative embodiment, the bonding layer is made from a material selected from the group consisting of silicon oxides, silicon oxynitride, silicon nitride and mixtures thereof. In this case too, the details given above in connection with the layer thicknesses of the carbon layer and the bonding layer also apply. According to the invention, the term silicon oxide is substantially to be understood as meaning silicon dioxide, but the PECVD process used to produce SiO₂ is not 100% stoichiometric, which means that the term silicon oxide alone is frequently used. According to the invention, these nonstoichiometric oxides are also encompassed by the term silicon oxide.

On account of the boundary layer located on the metal side, the carbon hard mask according to the invention can bond to various metals, such as Al, AlCu alloys, Cu or tungsten, with pure Al or AlCu alloys with a Cu content of 0.5-2%, preferably about 0.5% of Cu in Al, being preferred. A thin (10-40 nm) TiN layer (antireflection coating) may be present on the AlCu, in particular on Al and AlCu alloys. A barrier layer of Ta or TaN may be present on Cu. According to the invention, the bonding properties of the carbon hard mask are provided on these materials too on account of the introduction of the bonding layer. In the case of AlCu alloys, the Cu content is preferably 0.5 to 2% by weight, more preferably approximately 0.5% by weight.

Using the carbon hard mask according to the invention, it is preferably possible, at the abovementioned layer thicknesses of 80 to 250 nm, for metal layers, in particular Al or AlCu layers, with a thickness of from 500 to 1200 nm, preferably 850-1050 nm, to be etched cleanly and reproducibly.

Furthermore, the present invention provides a process for producing the carbon hard mask according to the invention, in which
first of all a layer which effects bonding between a metallic substrate and the carbon of the carbon hard mask is formed on the metallic substrate, and then to complete the carbon hard mask a carbon layer is formed on the layer which bonds to metals.

If the bonding layer is a nitrogen-doped carbon layer, it can easily be integrated into a process for applying the carbon layer, by first of all applying the nitrogen-doped carbon layer by means of a plasma-enhanced process for applying carbon, with a suitable quantity of nitrogen being added to the process. This has the advantage that there is no need to add a further, separate process step, with additional outlay on equipment, for applying the bonding layer.

It is customary to use a C-containing precursor, preferably C₂H₄ or C₃H₆, to apply carbon. To produce the N-doped layer, N₂ is added in a suitable quantity, so that an N-doped layer with a doping concentration of preferably 1 to 10% by weight of N, more preferably approximately 3 to 7, even more preferably approximately 5% by weight of N, is obtained. By way of example, it is preferably possible to use a mixture of C₃H₆ and N₂.

If the bonding layer is a silicon oxide, silicon oxynitride and/or silicon nitride layer, it is applied in the customary way in a separate step, i.e. by means of PECVD, which is followed by the application of the carbon layer.

The present invention also relates to the use of a carbon hard mask according to the invention in the patterning of metallic layers, in particular in semiconductor fabrication.

Overall, the present invention allows the reliable and reproducible patterning of metal tracks with considerable layer thicknesses combined with small line widths of the metal.

### BRIEF DESCRIPTION OF THE FIGURES

FIG. 1 shows a semiconductor structure according to the invention with etched resist.

FIG. 2 shows the state of the arrangement shown in FIG. 1 after etching of the mask to pattern the carbon hard mask below.

FIG. 3 shows the state after etching of the carbon hard mask and removal of the resist.

FIG. 4 shows the state after the actual etching of the metal layer with the aid of the carbon hard mask according to the invention.

FIG. 5 shows the state after removal of the carbon hard mask.

FIG. 6 shows an electron microscope image of the delamination of carbon at the edge of a metal-coated Si wafer substrate.

FIG. 7 shows a corresponding optical microscope image in the form of a plan view of a wafer edge without the use of the interlayer to promote bonding.

FIG. 8 shows an optical microscope image as in FIG. 7 with a carbon hard mask according to the invention.

The present invention is described in more detail below on the basis of the figures. However, the following description and exemplary embodiments are not to be regarded as restricting the scope of the invention in any way.

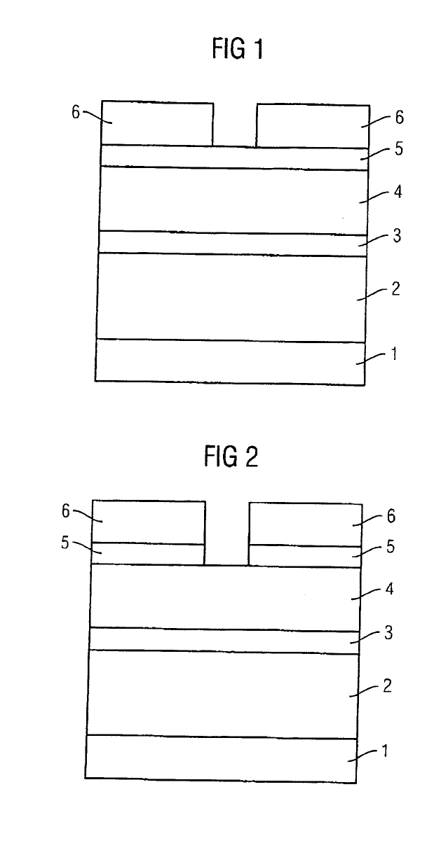

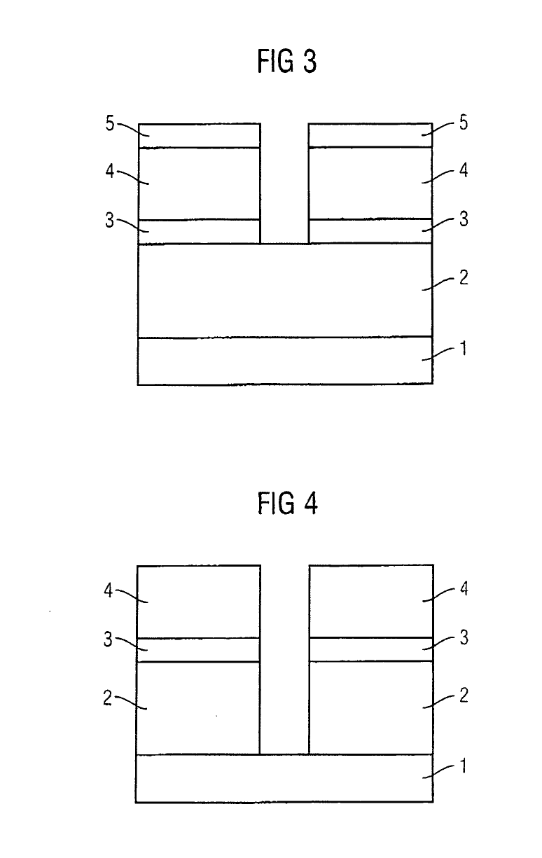

FIG. 1 shows a semiconductor structure in accordance with the present invention, having a metal layer 2 which is located on a substrate 1, e.g. a silicon substrate. The metal layer is, for example, pure Al, AlCu alloys, Cu or tungsten, and pure Al or AlCu alloys with a Cu content of 0.5-2%, preferably approximately 0.5% of Cu in Al, are preferred. A thin (10-40 nm) TiN layer (antireflection coating) may be present on the AlCu. The carbon hard mask according to the invention with a boundary layer or bonding layer 3 according to the invention, which may be either a nitrogen-doped carbon layer or a silicon oxide, silicon oxynitride or silicon nitride layer, arranged on the metal side is located on the metal layer. Above the bonding layer 3 is the carbon layer 4 of the carbon hard mask, which in turn is covered with a mask 5 of SiON for patterning of the carbon hard mask. A resist layer 6 which has already been patterned is located on the mask 5.

Using the structure illustrated in FIG. 1, a targeted or anisotropic SION dry etching step is carried out by plasma etching by means of fluorine-containing plasmas, preferably CHF₃, in order to pattern the mask layer 5. This state is shown in FIG. 2.

This is followed by a further dry etching step to pattern the carbon hard mask according to the invention by means of anisotropic dry etching using oxygen-containing gases, e.g. O₂+N₂. This state is illustrated in FIG. 4.

This is then followed by the actual patterning of the metal layer 2, which may preferably be carried out with the aid of chlorine-containing plasmas, such as BCl₃+Cl₂. The use of carbon as the main part of the hard mask allows the metal to be etched highly selectively. The SiON layer is removed during the metal etching. There is no detachment of the carbon hard mask, on account of the bonding layer according to the invention. This leads to very selective etching, as illustrated in FIG. 4.

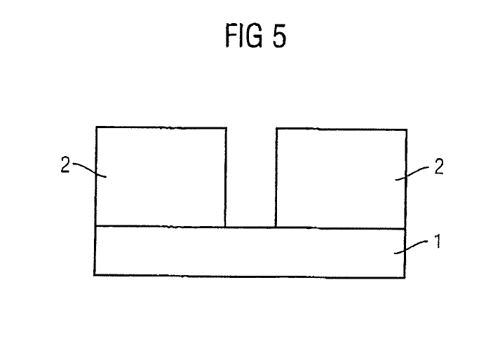

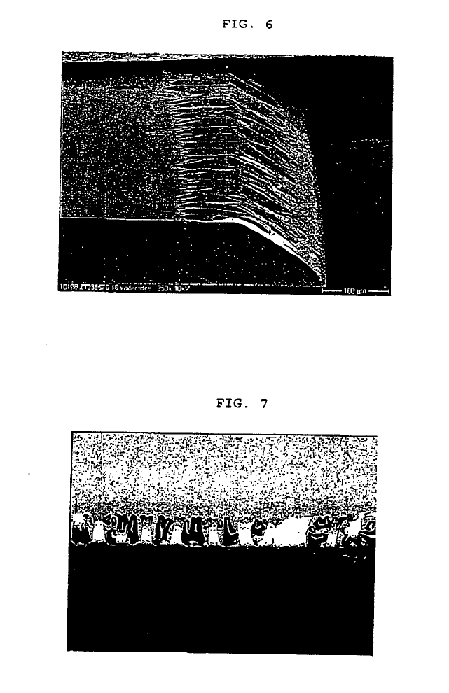

FIG. 5 shows the state after removal of the carbon hard mask, including the bonding layer, by means of oxygen plasma etching. What remains is a patterned metal layer 2 on a substrate 1. The carbon layer can easily be removed, e.g. by oxygen plasma treatment

### EXAMPLES

1. Adhesive strip tests

First of all, the bonding properties of the hard mask according to the invention on metals were tested. For comparison purposes, a pure carbon layer was tested.

For this purpose, a Al layer with a thickness of 900 nm was applied to an unprocessed Si wafer. A carbon layer with a thickness of 400 nm was deposited on the Al layer by means of PECVD. To test the hard masks according to the invention, an approximately 30 nm thick carbon layer doped with 10% of nitrogen was produced on the Al layer by an N precursor being added during the PECVD process for the deposition of C. The C precursor used was C₃H₆, with N₂ being admixed during production of the N-doped C layer. The overall thickness of the carbon hard mask layer produced in this way was 400 nm.

Furthermore, according to the invention a silicon oxide layer and, in another case, a silicon nitride layer and a silicon oxynitride layer was deposited, in each case in a thickness of 30 nm, on the Al layer by means of PECVD; precursors which can be used include SiH₄, N₂O and/or NH₃. This was followed by deposition of C by means of PECVD to a total layer thickness of 400 nm.

An adhesive tape (Scotch Crystal Clear Tape) was in each case applied to the above specimens, transversely across the wafer, using as far as possible a uniform pressure, until it became transparent, and the tape was then pulled off slowly.

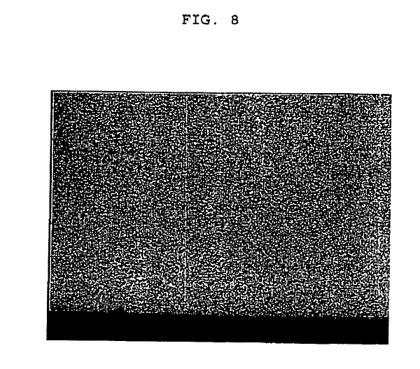

In the case of the pure carbon layer, delamination was observed, as illustrated in FIG. 6 and in a plan view of the edge region of the wafer shown in FIG. 7. The lower part of the illustration shown in FIG. 7 represents the region outside the wafer. The delaminated wafer edge can be seen in the center, and at the top is the wafer surface. The images reveal spontaneous detachments at the wafer edge even without the adhesive strip test. In the case where the bonding layers were introduced, in no case was it possible to observe delamination (as illustrated by FIG. 8). The above tests were repeated on substrates coated with AlCu, Cu, Wo, Ta, TaN and TiN, confirming the above results.

### EXAMPLE 2

Production of a metal patterning

An Al layer with a thickness of 950 nm was applied to a Si wafer with a SiO passivation layer by means of sputtering.

This was followed by the application of an N-doped carbon layer of approximately 20 nm by means of PECVD, in which the carbon precursor used was C₃H₆ and N₂ was fed to the plasma. The proportion of N precursor added was selected in such a way that approximately 5% by weight of nitrogen was present in the bonding layer. The addition of N₂ was stopped after a layer thickness of 15 nm had been reached. The PECVD process was then continued without the addition of the N precursor, so that a carbon layer with a thickness of approximately 250 nm was produced.

The structure obtained in this way was then provided with an SiON mask with a layer thickness of 25 nm for patterning of the carbon layer, with the aid of PECVD and a mixture of SiH₄, N₂O, He. Alternatively, an SiO layer of the same layer thickness was applied as a mask in the same way.

Finally, a resist was also applied to allow patterning of the SiON layer.

With the structure obtained in this way, the resist is then photolithographically patterned in a known way in order to open up the SiON, opening width: approx. 300 nm, spacings between the unetched regions: approx. 300 nm.

This was followed by an anisotropic dry etching step by plasma etching using CHF₃ plasma in order to etch the SiON layer.

The subsequent etching of the carbon layer and simultaneous removal of the resist were carried out by means of an oxygen etching plasma step.

It was then possible for the actual etching of the metal layer to be carried out selectively and without removal of the carbon layer with the aid of the bonding layer according to the invention by virtue of a targeted plasma etching step being carried out using a BCl₃/Cl₂ plasma. The SiON layer was removed in the process.

Optical tests revealed that there were substantially no hard mask defects, unlike with pure carbon hard masks (FIGS. 7 and 8).

After the carbon layer had been removed by oxygen plasma etching, the result was a patterned 950 nm thick Al layer on the Si substrate, with defect-free recesses which had been etched down to the substrate and a metal track width of approximately 300 nm. The defect-free patterning can be recognized from electron microscope images.

The process was equally successful if an SiO layer or SiON layer with a thickness of 15 nm was deposited instead of the N-doped carbon layer.

1. Carbon hard mask having a carbon layer and a bonding layer for bonding to metal or metal-containing inorganic materials.

2. Carbon hard mask according to claim 1, wherein the bonding layer is a nitrogen-doped carbon layer.

3. Carbon hard mask according to claim 2, wherein the nitrogen doping concentration in the bonding layer is from 1 to 10% by weight, preferably approximately 5% by weight.

4. Carbon hard mask according to claim 1, wherein the layer thickness of the bonding layer is from 2 to 100 nm, preferably 5 to 30 nm, more preferably 15 to 30 nm.

5. Carbon hard mask according to claim 1, wherein the thickness of the carbon layer is approximately 80 to 500 nm, preferably 200 to 500 nm.

6. Carbon hard mask according to claim 1, wherein the bonding layer is a layer of a material selected from the group consisting of silicon oxide, silicon oxynitride and silicon nitride.

7. Carbon hard mask according to claim 1, wherein it bonds to metal or metal-containing inorganic materials selected from the group consisting of Al, AlCu alloys, preferably with a Cu content of from 0.5 to 2% by weight, Cu, Wo, Ta, TaN and TiN.

8. Process for producing a carbon hard mark having a carbon layer and a bonding layer for bonding to metal, in which first of all a layer which effects bonding between a metallic substrate and the carbon of the carbon hard mask is formed on the metallic substrate, and then to complete the carbon hard mask a carbon layer is formed on the layer which bonds to metals.

9. Process according to claim 8, wherein a nitrogen doped carbon layer is formed as the layer which bonds to the metallic substrate.

10. Process according to claim 9, wherein the nitrogen-doped carbon layer which bonds to the metallic substrate is applied by means of a plasma-enhanced process for the application of carbon in which nitrogen is admixed.

11. Process according to claim 8, wherein a layer of a material selected from the group consisting of silicon oxide, silicon oxynitride and silicon nitride is formed as the layer which bonds to the metallic substrate.

12. Process according to claim 1, wherein the metal or metal-containing inorganic material used is selected from the group consisting of Al, AlCu alloys, preferably with a Cu content of from 0.5 to 2% by weight, Cu, Wo, Ta, TaN and TiN.

13. Use of a carbon hard mark according to claim 1 for the patterning of metallic layers, in particular in semiconductor fabrication.
